(19) United States
(12) Patent Application Publication
(10) Pub. No.: US 2025/0250667 A1
(43) Pub. Date: Aug. 7, 2025

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Kimihiko NAKATANI, Toyama-shi (JP)

(73) Assignee: KOKUSAI ELECTRIC CORPORATION, Tokyo (JP)

(21) Appl. No.: 19/087,044

(22) Filed: Mar. 21, 2025

Related U.S. Application Data
(63) Continuation of application No. PCT/JP2023/035988, filed on Oct. 3, 2023.

(30) Foreign Application Priority Data
Nov. 28, 2022 (JP) 2022-189404

(51) Int. Cl. C23C 16/04; C23C 16/52; H01L 21/02

(52) U.S. Cl. CPC C23C 16/045; C23C 16/52; H01L 21/02164; H01L 21/0228

(57) ABSTRACT

There is provided a technique that includes: forming a film containing a first and a second element, in a recess on a surface of a substrate by performing a cycle n times, the cycle including: (a) supplying a first substance that is chlorine-free and contains the first element to the substrate, thereby adsorbing X, which is at least a portion of a molecular structure of molecules constituting the first substance, on an upper portion of the recess; (b) supplying a second substance that is chlorine-free and contains the first element to the substrate, thereby adsorbing Y, which is at least a portion of a molecular structure of molecules constituting the second substance, on a portion where X is not adsorbed in the recess and forming a first layer; and (c) supplying a third substance containing the second element to the substrate, thereby modifying the first layer to a second layer.

### CROSS-REFERENCE TO RELATED APPLICATION

This application is a Bypass Continuation Application of PCT International Application No. PCT/JP2023/035988, filed on Oct. 3, 2023, and designating the United States, the international application being based upon and claiming the benefit of priority from Japanese Patent Application No. 2022-189404, filed on Nov. 28, 2022, the entire contents of which are incorporated herein by reference.

### TECHNICAL FIELD

The present disclosure relates to a processing method, a method of manufacturing a semiconductor device, a processing apparatus, and a recording medium.

### BACKGROUND

In the related art, as a process of manufacturing a semiconductor device, a process of forming a film in recesses such as trenches and holes provided on the surface of a substrate may be performed.

As semiconductor devices become smaller, there is a strong demand for improving the step coverage and other properties of films formed in recesses.

### SUMMARY

Some embodiments of the present disclosure provide a technique capable of improving the properties of a film formed in a recess.

According to embodiments of the present disclosure, there is provided a technique including forming a film containing a first element and a second element, in a recess on a surface of a substrate by performing a cycle n times, the cycle including: (a) supplying a first substance that is chlorine-free and contains the first element to the substrate, thereby adsorbing X, which is at least a portion of a molecular structure of molecules constituting the first substance, on an upper portion of the recess; (b) supplying a second substance that is chlorine-free and contains the first element to the substrate, thereby adsorbing Y, which is at least a portion of a molecular structure of molecules constituting the second substance, on a portion where X is not adsorbed in the recess and forming a first layer; and (c) supplying a third substance containing the second element to the substrate, thereby modifying the first layer to a second layer.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a processing apparatus suitably used in embodiments of the present disclosure, in which a portion of the process furnace is shown in a vertical cross section.

FIG. 2 is a schematic configuration view of the vertical process furnace of the processing apparatus suitably used in the embodiments of the present disclosure, in which a portion of the process furnace is shown in a cross section taken along line A-A in FIG. 1.

FIG. 3 is a schematic configuration diagram of a controller of the processing apparatus suitably used in the embodiments of the present disclosure, in which a control system of the controller is shown in a block diagram.

FIG. 4 is a diagram showing a processing sequence in embodiments of the present disclosure.

FIG. 5A is a schematic cross-sectional view showing a surface portion of a wafer having a recess on its surface after a first substance is supplied to the wafer.

FIG. 5B is a schematic cross-sectional view showing the surface portion of the wafer after a second substance is supplied to the wafer from the state of FIG. 5A.

FIG. 5C is a schematic cross-sectional view showing the surface portion of the wafer after a third substance is supplied to the wafer from the state of FIG. 5B under process conditions in which a film is formed at a first film formation rate when the second substance and the third substance are alternately supplied, and in which a film is not substantially formed when the first substance and the third substance are alternately supplied.

FIG. 5D is a schematic cross-sectional view showing the surface portion of the wafer after performing up to the n-th cycle of a film-forming step on the wafer from the state of FIG. 5C.

FIG. 5E is a schematic cross-sectional view showing the surface portion of the wafer after a modifying agent is supplied to the wafer from the state of FIG. 5D.

FIG. 6A is a schematic cross-sectional view showing a surface portion of a wafer having a recess on its surface after a first substance is supplied to the wafer.

FIG. 6B is a schematic cross-sectional view showing the surface portion of the wafer after a second substance is supplied to the wafer from the state of FIG. 6A.

FIG. 6C is a schematic cross-sectional view showing the surface portion of the wafer after a third substance is supplied to the wafer from the state of FIG. 6B under process conditions in which a film is formed at a first film formation rate when the second substance and the third substance are alternately supplied, and in which a film is formed at a second film formation rate lower than the first film formation rate when the first substance and the third substance are alternately supplied.

FIG. 6D is a schematic cross-sectional view showing the surface portion of the wafer after performing up to the n-th cycle of a film-forming step on the wafer from the state of FIG. 6C.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### EMBODIMENTS OF THE PRESENT DISCLOSURE

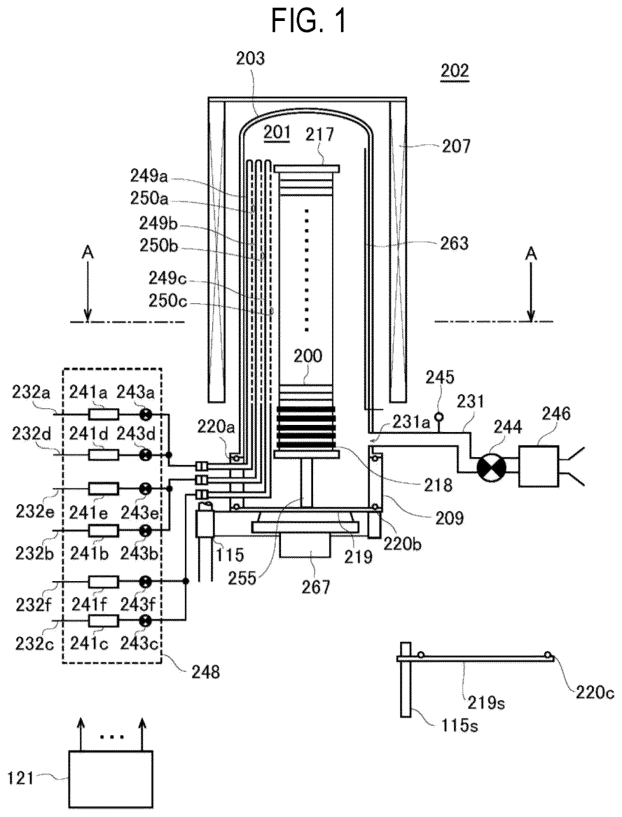

Embodiments of the present disclosure will now be described mainly with reference to FIGS. 1 to 4 and 5A to 5D. The drawings used in the following description are schematic, and the dimensional relationship, ratios, and the like of various elements shown in the drawings do not always match the actual ones. Further, the dimensional relationship, ratios, and the like of various elements between plural figures do not always match each other.

### (1) Configuration of Processing Apparatus

As shown in FIG. 1, a process furnace 202 includes a heater 207 as a temperature adjustor (a heating part). The heater 207 is formed in a cylindrical shape and is supported by a support plate so as to be vertically installed. The heater 207 also functions as an activation mechanism (an excitation part) that thermally activates (excites) a gas.

A reaction tube 203 is disposed inside the heater 207 to be concentric with the heater 207. The reaction tube 203 is made of, for example, a heat resistant material such as quartz or silicon carbide (SiC) and is formed in a cylindrical shape with its upper end closed and its lower end opened. A manifold 209 is disposed under the reaction tube 203 to be concentric with the reaction tube 203. The manifold 209 is made of, for example, a metal material such as stainless steel (SUS) and is formed in a cylindrical shape with its upper and lower ends opened. The upper end portion of the manifold 209 engages with the lower end portion of the reaction tube 203 so as to support the reaction tube 203. An O-ring 220a serving as a seal member is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed in the process chamber 201.

Nozzles 249a to 249c as first to third supply parts are provided in the process chamber 201 so as to penetrate through a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is provided adjacent to the nozzle 249b.

Mass flow controllers (MFCs) 241a to 241c, which are flow rate controllers (flow rate control parts), and valves 243a to 243c, which are opening/closing valves, are provided in the gas supply pipes 232a to 232c, respectively, sequentially from the upstream side of a gas flow. A gas supply pipe 232d is connected to the gas supply pipe 232a at the downstream side of the valve 243a. A gas supply pipe 232e is connected to the gas supply pipe 232b at the downstream side of the valve 243b. A gas supply pipe 232f is connected to the gas supply pipe 232c at the downstream side of the valve 243c. MFCs 241d to 241f and valves 243d to 243f are provided in the gas supply pipes 232d to 232f, respectively, sequentially from the upstream side of a gas flow. The gas supply pipes 232a to 232f are made of, for example, a metal material such as SUS.

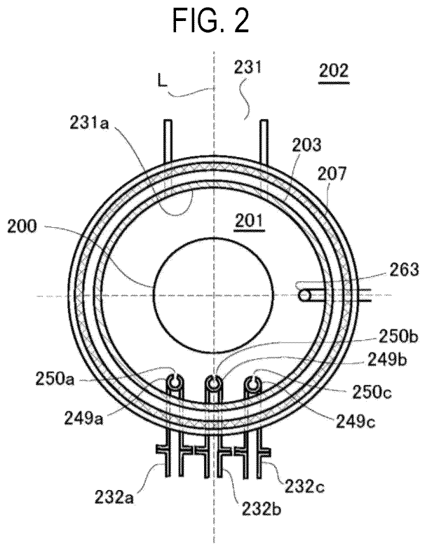

As shown in FIG. 2, each of the nozzles 249a to 249c is provided in an annular space (in a plane view) between an inner wall of the reaction tube 203 and the wafers 200 so as to extend upward from a lower portion of the inner wall of the reaction tube 203 to an upper portion thereof, that is, along an arrangement direction of the wafers 200. Specifically, each of the nozzles 249a to 249c is provided in a region horizontally surrounding a wafer arrangement region in which the wafers 200 are arranged at a lateral side of the wafer arrangement region, along the wafer arrangement region. In a plane view, the nozzle 249b is disposed so as to face an exhaust port 231a to be described later on a straight line with the centers of the wafers 200 loaded into the process chamber 201, which are interposed therebetween. The nozzles 249a and 249c are arranged so as to sandwich a straight line L passing through the nozzle 249b and the center of the exhaust port 231a from both sides along the inner wall of the reaction tube 203 (the outer peripheral portion of the wafers 200). The straight line L is also a straight line passing through the nozzle 249b and the centers of the wafers 200. That is, it can be said that the nozzle 249c is provided on the side opposite to the nozzle 249a with the straight line L interposed therebetween. The nozzles 249a and 249c are arranged in line symmetry with the straight line L as the axis of symmetry. Gas supply holes 250a to 250c for supplying a gas are formed on the side surfaces of the nozzles 249a to 249c, respectively. Each of the gas supply holes 250a to 250c is opened so as to oppose (face) the exhaust port 231a in a plane view, which enables a gas to be supplied toward the wafers 200. A plurality of gas supply holes 250a to 250c are formed from the lower portion of the reaction tube 203 to the upper portion thereof.

A chlorine-free first substance containing a first element is supplied from the gas supply pipe 232a into the process chamber 201 via the MFC 241a, the valve 243a, and the nozzle 249a.

A chlorine-free second substance containing a first element is supplied from the gas supply pipe 232b into the process chamber 201 via the MFC 241b, the valve 243b, and the nozzle 249b.

A third substance containing a second element different from the first element is supplied from the gas supply pipe 232c into the process chamber 201 via the MFC 241c, the valve 243c, and the nozzle 249c.

An inert gas is supplied from the gas supply pipes 232d to 232f into the process chamber 201 via the MFCs 241d to 241f, the valves 243d to 243f, the gas supply pipes 232a to 232c, and the nozzles 249a to 249c, respectively. The inert gas acts as a purge gas, a carrier gas, a dilution gas, or the like.

A first substance supply system mainly includes the gas supply pipe 232a, the MFC 241a, and the valve 243a. A second substance supply system mainly includes the gas supply pipe 232b, the MFC 241b, and the valve 243b. A third substance supply system mainly includes the gas supply pipe 232c, the MFC 241c, and the valve 243c. An inert gas supply system mainly includes the gas supply pipes 232d to 232f, the MFCs 241d to 241f, and the valves 243d to 243f.

One of or the entire above-described various supply systems may be configured as an integrated-type supply system 248 in which the valves 243a to 243f, the MFCs 241a to 241f, and so on are integrated. The integrated-type supply system 248 is connected to each of the gas supply pipes 232a to 232f. In addition, the integrated-type supply system 248 is configured such that operations of supplying various substances (various gases) into the gas supply pipes 232a to 232f (that is, the opening/closing operation of the valves 243a to 243f, the flow rate adjustment operation by the MFCs 241a to 241f, and the like) are controlled by a controller 121 which will be described later. The integrated-type supply system 248 is configured as an integral type or detachable-type integrated unit, and may be attached to and detached from the gas supply pipes 232a to 232f and the like on an integrated unit basis, so that the maintenance, replacement, extension, etc. of the integrated-type supply system 248 can be performed on an integrated unit basis.

The exhaust port 231a for exhausting an internal atmosphere of the process chamber 201 is provided below the sidewall of the reaction tube 203. As shown in FIG. 2, in a plane view, the exhaust port 231a is provided at a position opposing (facing) the nozzles 249a to 249c (the gas supply holes 250a to 250c) with the wafers 200 interposed therebetween. The exhaust port 231a may be provided from a lower portion of the sidewall of the reaction tube 203 to an upper portion thereof, that is, along the wafer arrangement region. An exhaust pipe 231 is connected to the exhaust port 231a. A vacuum exhaust device, for example, a vacuum pump 246, is connected to the exhaust pipe 231 via a pressure sensor 245, which is a pressure detector (pressure detection part) for detecting the internal pressure of the process chamber 201, and an auto pressure controller (APC) valve 244, which is a pressure regulator (pressure adjustment part). The APC valve 244 is configured to perform or stop a vacuum exhausting operation in the process chamber 201 by opening/closing the valve while the vacuum pump 246 is actuated. The APC valve 244 is also configured to adjust the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening cover configured to hermetically seal a lower end opening of the manifold 209, is provided under the manifold 209. The seal cap 219 is made of, for example, a metal material such as SUS and is formed in a disc shape. An O-ring 220b, which is a seal member making contact with the lower end of the manifold 209, is provided on an upper surface of the seal cap 219. A rotator 267 configured to rotate a boat 217, which will be described later, is installed under the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down.

A shutter 219s, which serves as a furnace opening cover configured to hermetically seal a lower end opening of the manifold 209 in a state where the seal cap 219 is lowered and the boat 217 is unloaded from the process chamber 201, is provided under the manifold 209. The shutter 219s is made of, for example, a metal material such as SUS and is formed in a disc shape. An O-ring 220c, which is a seal member making contact with the lower end of the manifold 209, is provided on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is adjusted such that an interior of the process chamber 201 achieves a desired temperature distribution. The temperature sensor 263 is provided along the inner wall of the reaction tube 203.

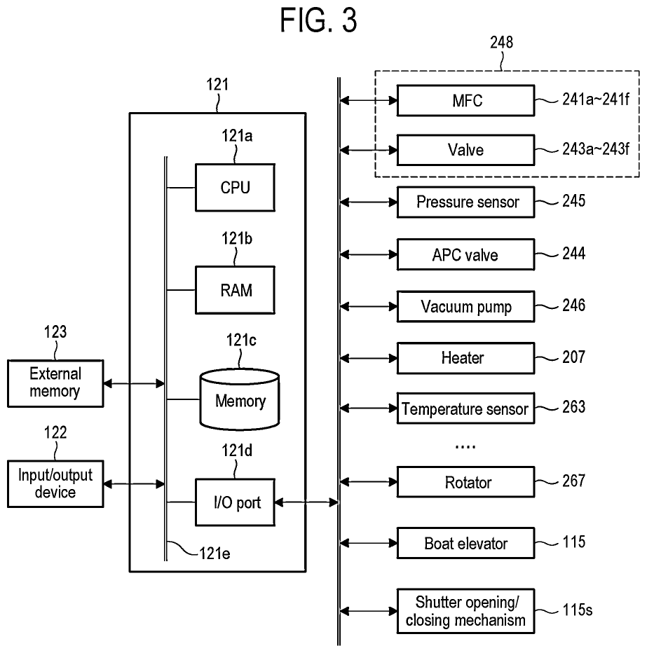

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121. Further, an external memory 123 may be connected to the controller 121. Here, the processing apparatus may be configured to include one control part, or may be configured to include a plurality of control parts. That is, control for performing a processing sequence to be described later may be performed using one control part, or may be performed using a plurality of control parts. Further, the plurality of control parts may be configured as a control system in which the plurality of control parts are connected to each other via a wired or wireless communication network, and the entire control system may perform control for performing the processing sequence to be described later. When the term “control part” is used in the present disclosure, it may include not only one control part but also a plurality of control parts or a control system configured by a plurality of control parts.

The memory 121c is configured by, for example, a flash memory, a hard disk drive (HDD), a solid state drive (SSD), or the like. A control program for controlling operations of a processing apparatus, a process recipe in which sequences and conditions of substrate processing to be described later are written, etc. are readably recorded and stored in the memory 121c. The process recipe functions as a program that causes, by the controller 121, the processing apparatus to execute each sequence in the substrate processing, which will be described later, to obtain an expected result. Hereinafter, the process recipe and the control program may be generally and simply referred to as a “program”. Furthermore, the process recipe may be simply referred to as a “recipe”. When the term “program” is used herein, it may indicate a case of solely including the recipe, a case of solely including the control program, or a case of including both the recipe and the control program. The RAM 121b is configured as a memory area (work area) in which programs or data read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to read and execute the control program from the memory 121c. The CPU 121a is also configured to read the recipe from the memory 121c according to an input of an operation command from the input/output device 122. The CPU 121a is configured to control the flow rate adjusting operation of various kinds of substances (gases) by the MFCs 241a to 241f, the opening/closing operation of the valves 243a to 243f, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotator 267 and adjusting the rotation speed of the boat 217, the operation of moving the boat 217 up and down by the boat elevator 115, the opening/closing operation of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is configured as a non-transitory computer-readable recording medium. Hereinafter, the memory 121c and the external memory 123 may be generally and simply referred to as a “recording medium”. When the term “recording medium” is used herein, it may indicate a case of solely including the memory 121c, a case of solely including the external memory 123, or a case of including both the memory 121c and the external memory 123. Furthermore, the program may be provided to the computer using communication means such as the Internet or a dedicated line, instead of using the external memory 123.

### (2) Processing Process

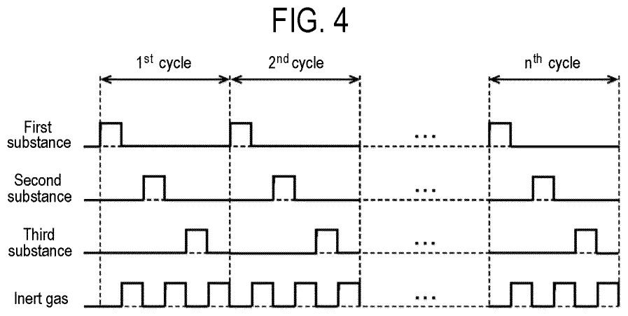

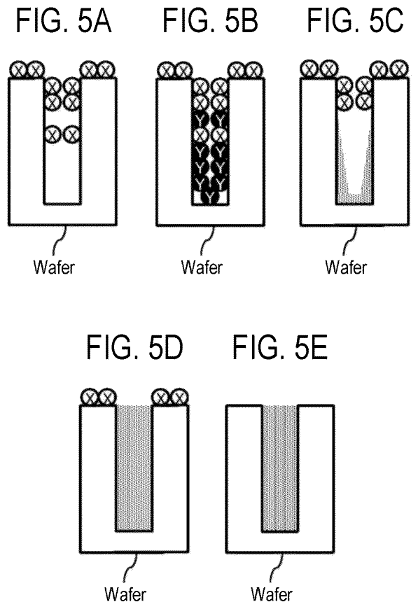

As a process of manufacturing a semiconductor device using the above-described processing apparatus, an example of a method of processing a substrate, that is, a processing sequence for forming a film in a recess such as a trench or hole provided in the surface of a wafer 200 as a substrate, will be described mainly with reference to FIGS. 4 and 5A to 5D. In the following description, the operations of the respective parts constituting the processing apparatus are controlled by the controller 121. The processing apparatus is also be referred to as a substrate processing apparatus, a film formation processing apparatus, or a film formation apparatus. The processing method is also be referred to as a substrate processing method, a film formation processing method, or a film formation method.

A processing sequence in the present embodiments include:
forming a film containing a first element and a second element, which is different from the first element, in a recess on the surface of a wafer 200 by performing a cycle n times (n is an integer of 1 or 2 or more), the cycle including:
(a) a step of supplying a chlorine-free first substance containing the first element to the wafer 200, thereby adsorbing at least a portion X of the molecular structure of molecules constituting the first substance on the upper portion of the recess (first substance supplying step);
(b) a step of supplying a chlorine-free second substance containing the first element to the wafer 200, thereby adsorbing at least a portion Y of the molecular structure of molecules constituting the second substance on the non-adsorbed portion of X in the recess so as to form a first layer (second substance supplying step); and
(c) a step of supplying a third substance containing the second element to the wafer 200, thereby modifying the first layer to a second layer (third substance supplying step), wherein the second substance supplying step is performed under process conditions in which the film is formed at a first film formation rate when the second substance and the third substance are alternately supplied, and in which the film is formed at a second film formation rate lower than the first film formation rate or is not substantially formed when the first substance and the third substance are alternately supplied.

In the following, a case will be described in which the third substance supplying step is performed under process conditions in which a film is formed at a first film formation rate when the second substance and the third substance are alternately supplied, and in which a film is not substantially formed when the first substance and the third substance are alternately supplied.

In the present disclosure, for the sake of convenience, the above-described processing sequence may be denoted as follows. The same denotation may be used in modifications and other embodiments to be described later.

(First substance→Second substance→Third substance)×n

When the term “wafer” is used in the present disclosure, it may refer to “a wafer itself” or “a stacked body of a wafer and certain layers or films formed on a surface of the wafer”. When the phrase “a surface of a wafer” is used in the present disclosure, it may refer to “a surface of a wafer itself” or “a surface of a certain layer formed on a wafer”. When the expression “a certain layer is formed on a wafer” is used in the present disclosure, it may mean that “a certain layer is formed directly on a surface of a wafer itself” or that “a certain layer is formed on a layer formed on a wafer”. When the term “substrate” is used in the present disclosure, it may be synonymous with the term “wafer”.

The term “substance” used in the present disclosure includes at least one selected from the group of a gaseous substance and a liquefied substance. The liquefied substance includes a misty substance. That is, each of a first substance, a second substance, and a third substance may include a gaseous substance, a liquefied substance such as a misty substance, or both of them.

The term “layer” used in the present disclosure includes at least one selected from the group of a continuous layer and a discontinuous layer. For example, each of a first layer and a second layer may include a continuous layer, a discontinuous layer, or both of them.

### (Wafer Charging and Boat Loading)

After the boat 217 is charged with a plurality of wafers 200 (wafer charging), the shutter 219s is moved by the shutter opening/closing mechanism 115s and the lower end opening of the manifold 209 is opened (shutter open). Thereafter, as shown in FIG. 1, the boat 217 charged with the plurality of wafers 200 is lifted up by the boat elevator 115 to be loaded into the process chamber 201 (boat loading). In this state, the seal cap 219 seals the lower end of the manifold 209 through the O-ring 220b. Thus, the wafers 200 are prepared (provided) inside the process chamber 201.

### (Pressure Adjustment and Temperature Adjustment)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information. Further, the wafers 200 in the process chamber 201 are heated by the heater 207 so as to achieve a desired processing temperature. At this time, the state of supplying electric power to the heater 207 is feedback-controlled based on the temperature information detected by the temperature sensor 263 so that the interior of the process chamber 201 achieves a desired temperature distribution. Further, the rotation of the wafers 200 by the rotator 267 is started. The exhaust of the interior of the process chamber 201 and the heating and rotation of the wafers 200 are continuously performed at least until the processing on the wafers 200 is completed.

### (Film-Forming Step)

Thereafter, the following first substance supplying step, second substance supplying step, and third substance supplying step are performed sequentially.

### [First Substance Supplying Step]

In this step, a chlorine (Cl)-free first substance containing a first element is supplied to the wafer 200 having a recess on its surface. More preferably, a halogen-free substance may be used as the chlorine-free first substance.

Specifically, the valve 243a is opened to allow the first substance to flow into the gas supply pipe 232a. The flow rate of the first substance is adjusted by the MFC 241a, and the first substance is supplied into the process chamber 201 via the nozzle 249a and is exhausted through the exhaust port 231a. In this operation, the first substance is supplied to the wafer 200 from the side of the wafer 200 (first substance supply). At this time, the valves 243d to 243f may be opened to allow an inert gas to be supplied into the process chamber 201 via the nozzles 249a to 249c, respectively.

By supplying the first substance to the wafer 200 under the process conditions shown below, it is possible to adsorb X, which is at least a portion of the molecular structure of molecules constituting the first substance, on the upper portion of the recess on the surface of the wafer 200, as shown in FIG. 5A. At this time, it is preferable to supply a slight shortage of the first substance to the wafer 200 under conditions in which the adsorption of X into the recess is non-saturated, i.e., under conditions in which a self-limit does not occur in the adsorption of X into the recess. For example, by making the supply time of the first substance shorter than the supply time of the second substance, it is possible to supply a slight shortage of the first substance to the wafer 200. Note that the process conditions shown below include conditions in which the adsorption of X into the recess is non-saturated.

The process conditions for supplying the first substance in the first substance supplying step are exemplified as follows:

Processing temperature: room temperature (25 degrees C.) to 800 degrees C., preferably 400 to 650 degrees C.

Processing pressure: 1 to 2,000 Pa, preferably 1 to 1,000 Pa

First substance supply flow rate: 0.001 to 3 slm, preferably 0.001 to 0.5 slm

First substance supply time: 0.1 to 60 seconds, preferably 0.1 to 30 seconds

Inert gas supply flow rate (for each gas supply pipe): 0 to 20 slm

Here, the notation of a numerical range such as “1 to 2,000 Pa” in the present disclosure means that the lower limit value and the upper limit value are included in the range. Therefore, for example, “1 to 2,000 Pa” means “1 Pa or more and 2,000 Pa or less”. The same applies to other numerical ranges. In the present disclosure, the processing temperature means the temperature of the wafer 200 or the internal temperature of the process chamber 201, and the processing pressure means the internal pressure of the process chamber 201. The processing time means the time that the processing continues. The supply flow rate of 0 slm means a case where no substance (gas) is supplied. These apply equally to the following description.

As the first substance, for example, a substance containing a partial structure in which an amino group and an alkyl group are bonded to the first element, or a partial structure in which an amino group and hydrogen are bonded to the first element, can be used. When such a substance is used as the first substance, X adsorbed on the upper portion of the recess can contain at least one selected from the group of a chemical bond between the first element and the alkyl group, a chemical bond between the first element and hydrogen, and a chemical bond between the first element and the amino group. That is, X can contain at least one selected from the group of the alkyl group, hydrogen, and the amino group, and the first element.

The first element includes, for example, silicon (Si). In this case, as the first substance, for example, a substance containing one or more chemical bonds between the first element and an alkyl group and three or less chemical bonds between the first element and an amino group in one molecule, or a substance containing one or more chemical bonds between the first element and hydrogen and three or less chemical bonds between the first element and an amino group in one molecule, can be used. Here, “one or more” and “three or less” refer to the number of chemical bonds, not the number of first elements. In the present disclosure, the chemical bond between the first element and an alkyl group refers to the bond between the first element and carbon (C) constituting the alkyl group. In addition, the chemical bond between the first element and an amino group refers to the bond between the first element and nitrogen (N) constituting the amino group.

As the first substance, for example, (dialkylamino)trialkylsilane such as (dimethylamino)trimethylsilane ((CH₃)₂NSi(CH₃)₃) containing three chemical bonds between the first element and an alkyl group and one chemical bond between the first element and an amino group in one molecule can be used.

In addition, as the first substance, for example, bis(dialkylamino)dialkylsilane such as bis(dimethylamino)dimethylsilane ([(CH₃)₂N]₂Si(CH₃)₂) containing two chemical bonds between the first element and an alkyl group and two chemical bonds between the first element and an amino group in one molecule can be used.

In addition, as the first substance, for example, tris(dialkylamino)alkylsilane such as tris(dimethylamino)methylsilane ([(CH₃)₂N]₃SiCH₃) containing one chemical bond between the first element and an alkyl group and three chemical bonds between the first element and an amino group in one molecule can be used.

In addition, as the first substance, for example, mono(dialkylamino)silane such as (diisobutylamino)silane ((C₄H₉)₂NSiH₃) or (diisopropylamino)silane ((C₃H₇)₂NSiH₃) containing three chemical bonds between the first element and hydrogen and one chemical bond between the first element and an amino group in one molecule can be used.

In addition, as the first substance, for example, bis(dialkylamino)silane such as bis(diethylamino)silane ([(C₂H₅)₂N]₂SiH₂) or bis(monoalkylamino)silane such as bis(tertiarybutylamino)silane ([(C₄H₉)NH]₂SiH₂) containing two chemical bonds between the first element and hydrogen and two chemical bonds between the first element and an amino group in one molecule can be used.

In addition, as the first substance, for example, tris(dialkylamino)silane such as tris(dimethylamino)silane ([(CH₃)₂N]₃SiH) containing one chemical bond between the first element and hydrogen and three chemical bonds between the first element and amino groups in one molecule can be used.

One or more of these can be used as the first substance. Note that “one”, “two”, and “three” in the above refer to the number of chemical bonds, not the number of first elements.

As the inert gas, nitrogen (N₂) gas and rare gases such as an argon (Ar) gas, a helium (He) gas, a neon (Ne) gas, and a xenon (Xe) gas can be used. One or more of these can be used as the inert gas. This point also applies to each step to be described later.

After X is adsorbed on the upper portion of the recess on the surface of the wafer 200, the valve 243a is closed to stop the supply of the first substance into the process chamber 201. Then, the interior of the process chamber 201 is vacuum-exhausted to remove a gaseous substance and the like remaining in the process chamber 201 from the process chamber 201. At this time, the valves 243d to 243f are opened to allow an inert gas to be supplied into the process chamber 201 via the nozzles 249a to 249c, respectively. The inert gas supplied from the nozzles 249a to 249c acts as a purge gas, whereby the interior of the process chamber 201 is purged (purging). It is preferable that the processing temperature during the purging in this step is the same as the processing temperature during the supply of the first substance.

### [Second Substance Supplying Step]

After the first substance supplying step is completed, a chlorine (Cl)-free second substance containing the first element is supplied to the wafer 200, i.e., the wafer 200 after X is adsorbed on the upper portion of the recess on the surface of the wafer 200. More preferably, a halogen-free substance may be used as the chlorine-free second substance.

Specifically, the valve 243b is opened to allow the second substance to flow into the gas supply pipe 232b. The flow rate of the second substance is adjusted by the MFC 241b, and the second substance is supplied into the process chamber 201 via the nozzle 249b and is exhausted through the exhaust port 231a. In this operation, the second substance is supplied to the wafer 200 from the side of the wafer 200 (second substance supply). At this time, the valves 243d to 243f may be opened to allow an inert gas to be supplied into the process chamber 201 via the nozzles 249a to 249c, respectively.

By supplying the second substance to the wafer 200 under the process conditions shown below, it is possible to form a first layer by adsorbing Y, which is at least a portion of the molecular structure of molecules constituting the second substance, on a non-adsorbed portion of X in the recess on the surface of the wafer 200, as shown in FIG. 5B. The first layer is a layer containing the first element. The non-adsorbed portion of X in the recess includes a bottom portion, a lower portion, and a center portion of the recess.

The process conditions for supplying the second substance in the second substance supplying step are exemplified as follows:

Processing temperature: room temperature (25 degrees C.) to 800 degrees C., preferably 400 to 650 degrees C.

Processing pressure: 1 to 2,000 Pa, preferably 1 to 1,000 Pa Second substance supply flow rate: 0.001 to 3 slm, preferably 0.001 to 0.5 slm Second substance supply time: 1 to 120 seconds, preferably 1 to 60 seconds Inert gas supply flow rate (for each gas supply pipe): 0 to 20 slm

As the second substance, a substance containing a partial structure in which an amino group and an alkoxy group are bonded to the first element can be used. When such a substance is used as the second substance, Y adsorbed on the non-adsorbed portion of X in the recess may include at least one selected from the group of a chemical bond between the first element and the alkoxy group and a chemical bond between the first element and the amino group. That is, Y may contain at least one selected from the group of the alkoxy group and the amino group, and the first element.

The first element includes, for example, Si. In this case, as the second substance, for example, a substance containing one or more chemical bonds between the first element and an alkoxy group and three or less chemical bonds between the first element and an amino group in one molecule can be used. Here, “one or more” and “three or less” refer to the number of chemical bonds, not the number of first elements. In the present disclosure, the chemical bond between the first element and an alkoxy group refers to the bond between the first element and oxygen (O) constituting the alkoxy group. In addition, the chemical bond between the first element and an amino group refers to the bond between the first element and N constituting the amino group, as described above.

As the second substance, for example, (dialkylamino)trialkoxysilane such as (dimethylamino)trimethoxysilane ((CH₃)₂NSi(OCH₃)₃) containing three chemical bonds between the first element and an alkoxy group and one chemical bond between the first element and an amino group in one molecule can be used.

In addition, as the second substance, for example, bis(dialkylamino)dialkoxysilane such as bis(dimethylamino)dimethoxysilane ([(CH₃)₂N]₂Si(OCH₃)₂) containing two chemical bonds between the first element and an alkoxy group and two chemical bonds between the first element and an amino group in one molecule can be used.

In addition, as the second substance, for example, tris(dialkylamino)alkoxysilane such as tris(dimethylamino)methoxysilane ([(CH₃)₂N]₃SiOCH₃) containing one chemical bond between the first element and an alkoxy group and three chemical bonds between the first element and an amino group in one molecule can be used.

One or more of these can be used as the second substance. Note that “one”, “two”, and “three” in the above refer to the number of chemical bonds, not the number of first elements.

Note that the controllability of film formation can be improved by using a substance having a higher reactivity (adsorptivity) than the first substance, as the second substance, i.e., by using a substance having a lower reactivity (adsorptivity) than the second substance, as the first substance.

After the first layer is formed in the recess on the surface of the wafer 200, the valve 243b is closed to stop the supply of the second substance into the process chamber 201. Then, a gaseous substance and the like remaining in the process chamber 201 are removed from the process chamber 201 (purging) according to the same processing procedures and process conditions as the purging in the first substance supplying step. It is preferable that the processing temperature during the purging in this step is the same as the processing temperature during the supply of the second substance.

### [Third Substance Supplying Step]

After the second substance supplying step is completed, a third substance containing, for example, oxygen (O) as a second element different from the first element, i.e., an oxidizing agent (oxidizing gas), is supplied to the wafer 200, that is, the wafer 200 after the first layer is formed in the recess.

Specifically, the valve 243c is opened to allow the third substance to flow into the gas supply pipe 232c. The flow rate of the third substance is adjusted by the MFC 241c, and the third substance is supplied into the process chamber 201 via the nozzle 249c and is exhausted through the exhaust port 231a. In this operation, the third substance is supplied to the wafer 200 from the side of the wafer 200 (third substance supply). At this time, the valves 243d to 243f may be opened to allow an inert gas to be supplied into the process chamber 201 via the nozzles 249a to 249c, respectively.

By supplying the third substance to the wafer 200 under the process conditions shown below, it is possible to oxidize at least a portion of the first layer to convert (modify) it to a second layer, as shown in FIG. 5C. At this time, the second element is added to the first layer containing the first element, and the second layer becomes a layer containing the first element and the second element, i.e., an oxidized layer containing the first element.

The process conditions for supplying the third substance in the third substance supplying step are exemplified as follows:
Processing temperature: 400 to 800 degrees C., preferably 500 to 800 degrees C.
Processing pressure: 1 to 4,000 Pa, preferably 1 to 1,000 Pa
Third substance supply flow rate: 0.1 to 10 slm, preferably 1 to 10 slm
Third substance supply time: 1 to 120 seconds, preferably 1 to 60 seconds
Inert gas supply flow rate (for each gas supply pipe): 0 to 20 slm

As the third substance (oxidizing agent), for example, an O-containing gas such as an oxygen (O₂) gas or vapor (H₂O) can be used. One or more of these can be used as the third substance.

After the first layer is oxidized and modified to the second layer, the valve 243c is closed to stop the supply of the third substance into the process chamber 201. Then, a gaseous substance and the like remaining in the process chamber 201 are removed from the process chamber 201 (purging) according to the same processing procedures and process conditions as the purging in the first substance supplying step. It is preferable that the processing temperature during the purging in this step is the same as the processing temperature during the supply of the third substance.

### [Performing Predetermined Number of Times]

By performing a cycle n times (n is an integer of 1 or 2 or more), the cycle including non-simultaneously performing the above-described first substance supplying step, second substance supplying step, and third substance supplying step, it is possible to form a film containing the first element and the second element in the recess on the surface of the wafer 200. As described above, when the first substance and the second substance contain Si as the first element and the third substance contains O as the second element, it is possible to form a silicon oxide film (SiO film) as a film containing the first element and the second element in the recess on the surface of the wafer 200. The above cycle is preferably repeated a plurality of times. That is, the thickness of the second layer formed per cycle may be set to be smaller than a desired film thickness, and the above cycle may be repeated a plurality of times until the thickness of a film formed by stacking second layers reaches the desired film thickness.

The above-mentioned process conditions for supplying the third substance in the third substance supplying step are process conditions under which a film is formed at a first film formation rate when the second substance and the third substance are alternately supplied, as described above, and are process conditions under which a film is not substantially formed when the first substance and the third substance are alternately supplied. In other words, the above-mentioned process conditions are also process conditions under which the reactivity between the second substance and the third substance is extremely higher than the reactivity between the first substance and the third substance.

In addition, the above-mentioned process conditions for supplying the third substance in the third substance supplying step are process conditions under which a film having a first thickness is formed per cycle when the second substance and the third substance are alternately supplied, and also include process conditions under which the thickness (second thickness) of the film formed per cycle when the first substance and the third substance are alternately supplied is substantially zero.

In addition, the above-mentioned process conditions for supplying the third substance in the third substance supplying step are process conditions under which a continuous film is formed when the second substance and the third substance are alternately supplied, and also include process conditions under which a film is not formed when the first substance and the third substance are alternately supplied.

For these reasons, during the film-forming step, as shown in FIG. 5C, the formation of a film can be effectively suppressed both in the upper portion of the recess on the surface of the wafer 200 and on the surface of the wafer 200 excluding the recess, and a state in which a film is not substantially formed continues. Further, if the film-forming step is further continued, as shown in FIG. 5D, a state appears in which a film is not substantially formed on the surface of the wafer 200 excluding the recess, and the recess on the surface of the wafer 200 is filled with a film.

### (After-Purging and Returning to Atmospheric Pressure)

After the film-forming step is completed, an inert gas acting as a purge gas is supplied into the process chamber 201 from each of the nozzles 249a to 249c and is exhausted through the exhaust port 231a. Thus, the interior of the process chamber 201 is purged and a gas, reaction by-products, and the like remaining in the process chamber 201 are removed from the process chamber 201 (after-purging). After that, the internal atmosphere of the process chamber 201 is substituted with an inert gas (inert gas substitution) and the internal pressure of the process chamber 201 is returned to the atmospheric pressure (returning to atmospheric pressure).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter close). The processed wafers 200 are unloaded from the reaction tube 203 and are then discharged from the boat 217 (wafer discharging).

### (3) Effects of the Present Embodiments

According to the present embodiments, one or more effects set forth below may be achieved.
(a) In the film-forming step, by performing a cycle n times on the wafer 200 having the recess on its surface, the cycle including the first substance supplying step, the second substance supplying step, and the third substance supplying step, it is possible to form a chlorine-free, high-quality, conformal film with high step coverage in the recess. In addition, it is possible to fill the recess with a void-free and seamless film with high accuracy.
(b) By performing the third substance supplying step under the process conditions in which a film is formed at the first film formation rate when the second substance and the third substance are alternately supplied, and in which a film is not substantially formed when the first substance and the third substance are alternately supplied, it is possible to suppress the formation of a film in the upper portion of the recess. As a result, it is possible to more effectively increase the step coverage of the film formed in the recess. In addition, it is possible to more effectively and accurately fill the recess with a void-free and seamless film.
(c) By using the above-mentioned various substances as the first substance and the second substance, it is possible to more effectively suppress the formation of a film on the upper portion of the recess on the surface of the wafer 200 during the film-forming step. As a result, it is possible to more effectively increase the step coverage of the film formed in the recess. In addition, it is possible to more effectively and accurately fill the recess with a void-free and seamless film.
(d) By using the above-mentioned oxidizing agent as the third substance, it is possible to form a chlorine-free, high-quality, conformal oxide film with high step coverage in the recess on the surface of the wafer 200. In addition, it is possible to accurately fill the recess with a void-free and seamless film by using the high-quality chlorine-free oxide film.
(e) The above-described effects can be obtained in the same way when a predetermined substance is arbitrarily selected from the above-mentioned various first substances, various second substances, various third substances, and various inert gases.

Note that the step performed under the process conditions in which a film is formed at a first film formation rate when the second substance and the third substance are alternately supplied, and in which a film is not substantially formed when the first substance and the third substance are alternately supplied, is not limited to the third substance supplying step. In addition, the step performed under the process conditions in which a film having a first thickness is formed per cycle when the second substance and the third substance are alternately supplied, and in which the thickness (second thickness) of the film formed per cycle when the first substance and the third substance are alternately supplied is substantially zero, is not limited to the third substance supplying step. In addition, the step performed under the process conditions in which a continuous film is formed when the second substance and the third substance are alternately supplied, and in which a film is not formed when the first substance and the third substance are alternately supplied, is not limited to the third substance supplying step. For example, under such process conditions, the first substance supplying step may be performed and the second substance supplying step may be performed. That is, at least one selected from the group of the first substance supplying step, the second substance supplying step, and the third substance supplying step may be performed under such process conditions, and each step, i.e., the film-forming step, may be performed under such process conditions. Note that the process conditions exemplified for each step described above include these process conditions. Even in these cases, the same effects as those described above can be obtained.

### (4) Modifications

The processing sequence in the present embodiments can be changed as in the following modifications. These modifications can be used in proper combination. Unless otherwise stated, the processing procedures and process conditions in each step of each modification can be the same as the processing procedures and process conditions in each step of the above-described processing sequence.

### Modification 1

The third substance supplying step may be performed under the process conditions in which a film is formed at a first film formation rate when the second substance and the third substance are alternately supplied, and in which a film is formed at a second film formation rate lower than the first film formation rate when the first substance and the third substance are alternately supplied.

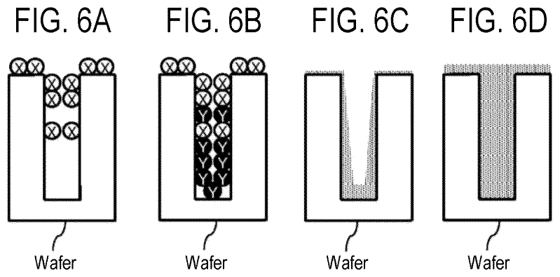

In the first substance supplying step of this modification, a chlorine-free first substance containing a first element is supplied to the wafer 200 having the recess on its surface according to the same processing procedures and process conditions as those in the first substance supplying step of the above-described embodiments. This makes it possible to adsorb X, which is at least a portion of the molecular structure of molecules constituting the first substance, on the upper portion of the recess on the surface of the wafer 200, as shown in FIG. 6A.

In addition, in the second substance supplying step of this modification, a chlorine-free second substance containing a first element is supplied to the wafer 200 after X is adsorbed on the upper portion of the recess on the surface according to the same processing procedures and process conditions as those in the second substance supplying step of the above-described embodiments. This makes it possible to form a first layer by adsorbing Y, which is at least a portion of the molecular structure of molecules constituting the second substance, on the non-adsorbed portion of X in the recess on the surface of the wafer 200, as shown in FIG. 6B. The first layer is a layer containing the first element. The non-adsorbed portion of X in the recess includes a bottom portion, a lower portion, and a center portion of the recess.

In this modification, the first substance and the second substance may be, for example, a substance containing a partial structure in which an amino group and an alkoxy group are bonded to the first element, a partial structure in which an amino group and an alkyl group are bonded to the first element, or a partial structure in which an amino group and hydrogen are bonded to the first element. When such substances are used as the first substance and the second substance, X, which is at least a portion of the molecular structure of the molecules constituting the first substance to be adsorbed on the upper portion of the recess, may contain at least one selected from the group of the chemical bond between the first element and the alkoxy group, the chemical bond between the first element and the alkyl group, the chemical bond between the first element and hydrogen, and the chemical bond between the first element and the amino group. That is, X may include at least one selected from the group of the alkoxy group, the alkyl group, hydrogen, and the amino group, and the first element. In addition, Y, which is at least a portion of the molecular structure of the molecules constituting the second substance to be adsorbed to the non-adsorption portion of X in the recess, may include at least one selected from the group of the chemical bond between the first element and the alkoxy group, the chemical bond between the first element and the alkyl group, the chemical bond between the first element and hydrogen, and the chemical bond between the first element and the amino group. That is, Y may include at least one selected from the group of the alkoxy group, the alkyl group, hydrogen, and the amino group, and the first element.

Here, it is preferable that the number of chemical bonds between the first element and the amino group contained in one molecule of the first substance is greater than the number of chemical bonds between the first element and the amino group contained in one molecule of the second substance. That is, it is preferable that the number of amino groups contained in one molecule of the first substance is greater than the number of amino groups contained in one molecule of the second substance.

The first element includes, for example, Si. In this case, in this modification, the first substance may be, for example, a substance containing, in one molecule, two or more chemical bonds between the first element and the amino group, two or less chemical bonds between the first element and the alkoxy group, two or less chemical bonds between the first element and the alkyl group, or two or less chemical bonds between the first element and hydrogen. In addition, in this modification, the second substance may be, for example, a substance containing, in one molecule, one chemical bond between the first element and the amino group, three chemical bonds between the first element and the alkoxy group, three chemical bonds between the first element and the alkyl group, or three chemical bonds between the first element and hydrogen. Here, “two or more”, “two or less”, “one”, and “three” refer to the number of chemical bonds, not the number of first elements.

That is, in this modification, the first substance may be, for example, bis(dialkylamino)dialkoxysilane such as bis(dimethylamino)dimethoxysilane ([(CH₃)₂N]₂Si(OCH₃)₂) containing, in one molecule, two chemical bonds between the first element and the amino group and two chemical bonds between the first element and the alkoxy group.

In addition, in this modification, the first substance may be, for example, tris(dialkylamino)alkoxysilane such as tris(dimethylamino)methoxysilane ([(CH₃)₂N]₃SiOCH₃) containing, in one molecule, three chemical bonds between the first element and the amino group and one chemical bond between the first element and the alkoxy group.

In addition, in this modification, the first substance may be, for example, bis(dialkylamino)dialkylsilane such as bis(dimethylamino)dimethylsilane ([(CH₃)₂N]₂Si(CH₃)₂) containing, in one molecule, two chemical bonds between the first element and the amino group and two chemical bonds between the first element and the alkyl group.

In addition, in this modification, the first substance may be, for example, tris(dialkylamino)alkylsilane such as tris(dimethylamino)methylsilane ([(CH₃)₂N]₃SiCH₃) containing, in one molecule, three chemical bonds between the first element and the amino group and one chemical bond between the first element and the alkyl group.

In addition, in this modification, the first substance may be, for example, bis(dialkylamino)silane such as bis(diethylamino)silane ([(C₂H₅)₂N]₂SiH₂) or bis(monoalkylamino)silane such as bis(tertiarybutylamino)silane ([(C₄H₉)NH]₂SiH₂) containing, in one molecule, two chemical bonds between the first element and the amino group and two chemical bonds between the first element and hydrogen.

In addition, in this modification, the first substance may be tris(dialkylamino)silane such as tris(dimethylamino)silane ([(CH₃)₂N]₃SiH) containing, in one molecule, three chemical bonds between the first element and the amino group and one chemical bond between the first element and hydrogen.

In this modification, one or more of these may be used as the first substance. Note that “one”, “two”, and “three” in the above refer to the number of chemical bonds, not the number of first elements.

In addition, in this modification, the second substance may be, for example, (dialkylamino)trialkoxysilane such as (dimethylamino)trimethoxysilane ((CH₃)₂NSi(OCH₃)₃) containing, in one molecule, one chemical bond between the first element and the amino group and three chemical bonds between the first element and the alkoxy group.

In addition, in this modification, the second substance may be, for example, (dialkylamino)trialkylsilane such as (dimethylamino)trimethylsilane ((CH₃)₂NSi(CH₃)₃) containing, in one molecule, one chemical bond between the first element and the amino group and three chemical bonds between the first element and the alkyl group.

In addition, in this modification, the second substance may be, for example, mono(dialkylamino)silane such as (diisobutylamino)silane ((C₄H₉)₂NSiH₃) or (diisopropylamino)silane ((C₃H₇)₂NSiH₃) containing, in one molecule, one chemical bond between the first element and the amino group and three chemical bonds between the first element and hydrogen.

In this modification, one or more of these may be used as the second substance. Note that “one” and “three” in the above refer to the number of chemical bonds, not the number of first elements.

Note that the controllability of film formation can be improved by using a substance having a higher reactivity (adsorptivity) than the first substance, as the second substance, i.e., by using a substance having a lower reactivity (adsorptivity) than the second substance, as the first substance.

In addition, by using a substance having fewer amino groups contained in one molecule than the first substance, as the second substance, the amount of adsorption (adsorption density) of Y in the recess can be made greater (higher) than the amount of adsorption (adsorption density) of X in the recess, and the amount of adsorption (adsorption density) of the first element derived from the second substance in the recess can be made greater (higher) than the amount of adsorption (adsorption density) of the first element derived from the first substance in the recess. That is, the amount of adsorption (adsorption density) of the first element in the bottom portion, lower portion, or center portion of the recess can be made greater (higher) than the amount of adsorption (adsorption density) of the first element in the upper portion of the recess. This is one factor that makes the thickness of the layer containing the first element and the second element formed in the bottom portion, lower portion, or center portion of the recess per cycle thicker than the thickness of the layer containing the first element and the second element formed in the upper portion of the recess per cycle.

In the third substance supplying step of this modification, a third substance containing, for example, O as a second element, i.e., an oxidizing agent (oxidizing gas), is supplied to the wafer 200 after the first layer is formed in the recess according to the same processing procedures as those in the third substance supplying step of the above-described embodiments. This makes it possible to oxidize at least a portion of the first layer to convert (modify) it to a second layer, as shown in FIG. 6C. At this time, the second element is added to the first layer containing the first element, and the second layer becomes a layer containing the first element and the second element, i.e., an oxidized layer containing the first element.

When the above-mentioned various substances are used as the first substance and the second substance, in this modification, for example, an O-containing gas (+H-containing gas) such as ozone (O₃) or oxygen (O₂)+hydrogen (H₂) or O-containing radicals such as oxygen (O) radicals or hydroxyl (OH) radicals can be used as the third substance (oxidizing agent). One or more of these can be used as the third substance.

Note that in the present disclosure, the description of two substances such as “O₂+H₂” together means a mixture of H₂ and O₂. When supplying the mixture, the two substances may be mixed (pre-mixed) in a supply pipe and then supplied into the process chamber 201, or the two substances may be supplied separately from different supply pipes into the process chamber 201 and then mixed (post-mixed) in the process chamber 201.

When at least one selected from the group of O₃, O₂+H₂, O radicals, and OH radicals is used as the third substance, the process conditions for supplying the third substance in the third substance supplying step are exemplified as follows:
Processing temperature: room temperature (25 degrees C.) to 800 degrees C., preferably 200 to 800 degrees C.
Processing pressure: 1 to 4,000 Pa, preferably 1 to 1,000 Pa
Third substance supply flow rate: 0.01 to 10 slm, preferably 1 to 10 slm
Third substance supply time: 1 to 120 seconds, preferably 1 to 60 seconds
Inert gas supply flow rate (for each gas supply pipe): 0 to 20 slm

In addition, when at least one selected from the group of the above-mentioned bis(dialkylamino)dialkoxysilane and the above-mentioned tris(dialkylamino)alkoxysilane is used as the first substance and the above-mentioned (dialkylamino)trialkoxysilane is used as the second substance, in this modification, in addition to the above-mentioned various substances, for example, an O-containing gas such as O₂ or H₂O can be used as the third substance (oxidizing agent). One or more of these can be used as the third substance.

When at least one selected from the group of O₂ and H₂O is used as the third substance, the process conditions for supplying the third substance in the third substance supplying step can be the same as the process conditions in the third substance supplying step of the above-described embodiments.

Even in this modification, by performing a cycle n times (n is an integer of 1 or 2 or more), the cycle including non-simultaneously performing the above-described first substance supplying step, second substance supplying step, and third substance supplying step, it is possible to form a film containing the first element and the second element in the recess on the surface of the wafer 200, as shown in FIG. 6D. As described above, when the first substance and the second substance contain Si as the first element and the third substance contains O as the second element, it is possible to form a SiO film in the recess on the surface of the wafer 200.

The above-mentioned process conditions for supplying the third substance in the third substance supplying step are process conditions under which a film is formed at a first film formation rate when the second substance and the third substance are alternately supplied, as described above, and are process conditions under which a film is formed at the second film formation rate lower than the first film formation rate when the first substance and the third substance are alternately supplied.

In addition, the above-mentioned process conditions for supplying the third substance in the third substance supplying step are process conditions under which a film having a first thickness is formed per cycle when the second substance and the third substance are alternately supplied, and are also process conditions under which a film having a second thickness thinner than the first thickness is formed per cycle when the first substance and the third substance are alternately supplied. The second thickness is, for example, a thickness less than one atomic layer.

In addition, the above-mentioned process conditions for supplying the third substance in the third substance supplying step are process conditions under which a continuous film is formed when the second substance and the third substance are alternately supplied, and also include process conditions under which a discontinuous island-shaped film is formed when the first substance and the third substance are alternately supplied.

In addition, the above-mentioned process conditions for supplying the third substance in the third substance supplying step are process conditions under which a continuous film having a thickness T₁ is formed when the second substance and the third substance are alternately supplied a predetermined number of times, and are also process conditions under which a film having a thickness T₂ less than the thickness T₁ is formed when the first substance and the third substance are alternately supplied a predetermined number of times.

For these reasons, during the film-forming step, as shown in FIG. 6C, a layer (film) containing the first element and the second element and having a thickness thinner than a layer (film) containing the first element and the second element formed on the bottom portion, lower portion, or center portion of the recess is formed both in the upper portion of the recess on the surface of the wafer 200 and on the surface of the wafer 200 excluding the recess, each time a cycle is performed. Further, if the film-forming step is further continued, as shown in FIG. 6D, a state appears in which the recess on the surface of the wafer 200 is filled with a film, and a film having a predetermined thickness is formed on the surface of the wafer 200 excluding the recess.

This modification also obtains substantially the same effects as those of the above-described embodiments.

That is, it is possible to form a chlorine-free, high-quality, conformal film with high step coverage in the recess on the surface of the wafer 200. It is also possible to accurately fill the recess with a void-free and seamless film by using the chlorine-free, high-quality film.

In addition, by performing the third substance supplying step under the process conditions in which a film is formed at the first film formation rate when the second substance and the third substance are alternately supplied, and in which a film is formed at the second film formation rate lower than the first film formation rate when the first substance and the third substance are alternately supplied, it is possible to form a film having an appropriate thickness in the upper portion of the recess while suppressing the formation of a film in the upper portion of the recess on the surface of the wafer 200, and it is possible to improve the throughput of substrate processing, i.e., the productivity of substrate processing.

In addition, by using the above-mentioned various substances as the first substance and the second substance, it is possible to effectively form a film having an appropriate thickness in the upper portion of the recess while suppressing the formation of a film in the upper portion of the recess on the surface of the wafer 200, and it is possible to more effectively improve the throughput of substrate processing, i.e., the productivity of substrate processing.

In addition, by using the above-mentioned oxidizing agent as the third substance, it is possible to form a chlorine-free, high-quality, conformal oxide film with high step coverage in the recess on the surface of the wafer 200. In addition, it is possible to accurately fill the recess with a void-free and seamless film by using the high-quality chlorine-free oxide film.

The above-described effects can be obtained in the same way when a predetermined substance is arbitrarily selected from the above-mentioned various first substances, various second substances, various third substances, and various inert gases.

Note that the step performed under the process conditions in which a film is formed at a first film formation rate when the second substance and the third substance are alternately supplied, and in which a film is formed at a second film formation rate lower than the first film formation rate when the first substance and the third substance are alternately supplied, is not limited to the third substance supplying step. In addition, the step performed under the process conditions in which a film having a first thickness is formed per cycle when the second substance and the third substance are alternately supplied, and in which a film having a second thickness thinner than the first thickness is formed per cycle when the first substance and the third substance are alternately supplied, is not limited to the third substance supplying step. In addition, the step performed under the process conditions in which a continuous film is formed when the second substance and the third substance are alternately supplied, and in which a discontinuous island-shaped film is formed when the first substance and the third substance are alternately supplied, is not limited to the third substance supplying step. In addition, the step performed under the process conditions in which a continuous film having a thickness T₁ is formed when the second substance and the third substance are alternately supplied a predetermined number of times, and in which a film having a thickness T₂ less than the thickness T₁ is formed when the first substance and the third substance are alternately supplied a predetermined number of times, is not limited to the third substance supplying step. For example, under such process conditions, the first substance supplying step may be performed and the second substance supplying step may be performed. As described above, the use of a substance having fewer amino groups in one molecule than the first substance, as the second substance, that is, the use of a substance having more amino groups in one molecule than the second substance, as the first substance, can also be said to be included in such process conditions. That is, at least one selected from the group of the first substance supplying step, the second substance supplying step, and the third substance supplying step may be performed under such process conditions, and each step, i.e., the film-forming step, may be performed under such process conditions. Note that the process conditions exemplified for each step described above include these process conditions. Even in these cases, the same effects as those described above can be obtained.

### Modification 2

As in the processing sequence shown below, in the film-forming step, a cycle may be performed n times (n is an integer of 1 or 2 or more), the cycle including performing the first substance supplying step and performing the second substance supplying step and the third substance supplying step alternately m times (m is an integer of 1 or 2 or more).

[First substance→(Second substance→Third substance)×m]×n

This modification also obtains the same effects as those of the above-described embodiments. In addition, according to this modification, it is possible to improve the controllability of the composition ratio of a film formed in the recess.

Note that, in this modification, the value of m may be changed in accordance with an increase in the number of cycles performed. For example, the value of m may be set to be small in the initial stage of the film-forming step, and may be gradually increased in accordance with the progress of the process of filling the recess with the film. This makes it possible to suppress a gradual decrease in productivity as the process of filling the recess with the film progresses.

### Modification 3

When the cycle including non-simultaneously performing the above-described first substance supplying step, second substance supplying step, and third substance supplying step are performed a predetermined number of times, the process conditions for supplying the first substance in the first substance supplying step may be changed in accordance with an increase in the number of cycles performed.

For example, in the initial stage of the film-forming step, the supply time of the first substance in the first substance supplying step may be set to be relatively long, and its value (supply time) may be gradually shortened in accordance with the progress of the process of filling the recess with a film. In addition, for example, in the initial stage of the film-forming step, the supply flow rate of the first substance in the first substance supplying step may be set to be relatively large, and its value (supply flow rate) may be gradually reduced in accordance with the progress of the process of filling the recess with the film. In addition, for example, in the initial stage of the film-forming step, the processing pressure for supplying the first substance in the first substance supplying step may be set to be relatively high, and its value (processing pressure) may be gradually reduced in accordance with the progress of the process of filling the recess with the film. In addition, for example, in the initial stage of the film-forming step, the partial pressure of the first substance in the process chamber 201 when the first substance is supplied in the first substance supplying step may be set to be relatively high, and its value (partial pressure) may be gradually lowered as the process of filling the recess with the film progresses.

This modification also obtains the same effects as those of the above-described embodiments. In addition, according to this modification, it is possible to suppress a gradual decrease in productivity as the process of filling the recess with the film progresses.

### Modification 4

As shown in FIG. 5D, X, which is at least a portion of the molecular structure of the molecules constituting the first substance, may remain adsorbed on the surface of the wafer 200 after the film-forming step is performed. In addition, X may remain at the interface between the film and the recess, or may remain in the film. Therefore, as shown in the processing sequence below, after the film-forming step, a step (modifying step) of modifying the film formed in the recess and the surface of the wafer 200 by supplying a modifying agent to the wafer 200 may be further performed (n and m are integers of 1 or 2 or more). For example, an O-containing gas (+H-containing gas) such as O₃ or O₂+H₂ or O-containing radicals such as O radicals or OH radicals, which are exemplified as the third substance, can be used as the modifying agent.

(First substance→Second substance→Third substance)×n→Modifying agent

[First substance→(Second substance→Third substance)×m]×n→Modifying agent

The processing procedures in the modifying step can be the same as the processing procedures in the third substance supplying step of the above-described embodiments.

The process conditions for supplying the modifying agent in the modifying step are exemplified as follows:
Processing temperature: room temperature (25 degrees C.) to 1,000 degrees C., preferably 200 to 800 degrees C.
Processing pressure: 1 to 4,000 Pa, preferably 1 to 1,000 Pa
Modifying agent supply flow rate: 0.01 to 10 slm, preferably 1 to 10 slm
Modifying agent supply time: 1 to 18,000 seconds, preferably 120 to 10,800 seconds
Inert gas supply flow rate (for each gas supply pipe): 0 to 20 slm

This modification also obtains the same effects as those of the above-described embodiments. In addition, according to this modification, by performing the modifying step, it is possible to remove X remaining at the interface between the film and the recess from the interface. In addition, it is possible to remove X remaining in the film from the film. As a result, it is possible to improve the film quality of the film formed in the recess. Moreover, as shown in FIG. 5E, it is also possible to remove X adsorbed on the surface of the wafer 200 from the surface of the wafer 200.

Note that the modifying step can be performed not only at the timing of the end of the film formation but also at any timing during the film formation, as shown below (n, m, and p are integers of 1 or 2 or more).

[(First substance→Second substance→Third substance)×n→Modifying]×p

[[First substance→(Second substance→Third substance)×m]×n→Modifying]×p

These cases also obtain the same effects as those of the above-described embodiments. In addition, by performing the modifying step at the timing of the end of the film formation and at any timing during the film formation, it is possible to further improve the film quality of the film formed in the recess. In addition, as shown in FIG. 5E, it is also possible to remove X adsorbed on the surface of the wafer 200 from the surface of the wafer 200.

It is preferable that the film-forming step and the modifying step are performed in the same process chamber (in-situ). This makes it possible to perform the film-forming step and the modifying step without exposing the wafer 200 to the atmosphere, that is, while keeping the surface of the wafer 200 in a clean state.

### OTHER EMBODIMENTS OF THE PRESENT DISCLOSURE

The embodiments of the present disclosure are specifically described above. However, the present disclosure is not limited to the above-described embodiments, and various changes can be made without departing from the gist thereof.

For example, the present disclosure can be suitably applied to a case of forming, in addition to a SiO film, oxide films containing semiconductor elements such as a silicon oxynitride film (SiON film), a silicon oxycarbonitride film (SiOCN film), a silicon oxycarbide film (SiOC film), and oxide films containing metal elements such as a hafnium oxide film (HfO film), a zirconium oxide film (ZrO film), an aluminum oxide film (AlO film), and the like, in the recess on the surface of the substrate. This embodiment also obtains the same effects as those of the above-described embodiments.

Recipes used in each process may be prepared individually according to the processing contents and may be recorded and stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for a single processing apparatus to form films of various kinds, composition ratios, qualities, and thicknesses with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the processing apparatus. Once the recipes are modified, the modified recipes may be installed in the processing apparatus via a telecommunication line or a recording medium storing the recipes. In addition, the existing recipes already installed in the existing processing apparatus may be directly modified by operating the input/output device 122 of the processing apparatus.

An example in which a film is formed using a batch-type processing apparatus capable of processing a plurality of substrates at a time is described in the above-described embodiments. The present disclosure is not limited to the above-described embodiments, but may be suitably applied, for example, to a case where a film is formed using a single-wafer type processing apparatus capable of processing a single substrate or several substrates at a time. In addition, an example in which a film is formed using a processing apparatus provided with a hot-wall-type process furnace is described in the above-described embodiments. The present disclosure is not limited to the above-described embodiments, but may be suitably applied to a case where a film is formed using a processing apparatus provided with a cold-wall-type process furnace.

In addition, an example in which the above-described processing sequence is performed in the same process chamber of the same processing apparatus (in-situ) is described in the above-described embodiments. The present disclosure is not limited to the above-described embodiments. For example, any step and any other step of the above-described processing sequence may be performed in different process chambers of different processing apparatuses (ex-situ), or may be performed in different process chambers of the same processing apparatus.

Even in the case of using these processing apparatuses, each process may be performed according to the same processing procedures and process conditions as those in the above-described embodiments and modifications, and the same effects as those of the above-described embodiments and modifications can be obtained.

The above-described embodiments and modifications may be used in proper combination. The processing procedures and process conditions used in this case may be the same as, for example, the processing procedures and process conditions in the above-described embodiments and modifications.

According to the present disclosure in some embodiments, it is possible to improve the properties of a film formed in a recess.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method comprising:
forming a film containing a first element and a second element, which is different from the first element, in a recess on a surface of a substrate by performing a cycle n times (n is an integer of 1, or greater than or equal to 2), the cycle including:
(a) supplying a first substance that is chlorine-free and contains the first element to the substrate, thereby adsorbing X, which is at least a portion of a molecular structure of molecules constituting the first substance, on an upper portion of the recess;
(b) supplying a second substance that is chlorine-free and contains the first element to the substrate, thereby adsorbing Y, which is at least a portion of a molecular structure of molecules constituting the second substance, on a portion where X is not adsorbed in the recess and forming a first layer; and
(c) supplying a third substance containing the second element to the substrate, thereby modifying the first layer to a second layer,
wherein (c) is performed under process conditions in which the film is formed at a first film formation rate when the second substance and the third substance are alternately supplied, and in which the film is formed at a second film formation rate lower than the first film formation rate or is substantially not formed when the first substance and the third substance are alternately supplied.

2. The processing method of claim 1, wherein (c) is performed under process conditions in which the film with a first thickness is formed per cycle when the second substance and the third substance are alternately supplied, and in which the film having a second thickness thinner than the first thickness is formed per cycle when the first substance and the third substance are alternately supplied.

3. The processing method of claim 2, wherein the second thickness is substantially zero.

4. The processing method of claim 2, wherein the second thickness is less than a thickness of one atomic layer.

5. The processing method of claim 1, wherein (c) is performed under process conditions in which the film is continuously formed when the second substance and the third substance are alternately supplied, and in which the film is formed in a discontinuous island-shape or the film is not formed when the first substance and the third substance are alternately supplied.

6. The processing method of claim 1, wherein (c) is performed under process conditions in which the film is formed with a thickness T₁ and is formed continuously when the second substance and the third substance are alternately supplied a predetermined number of times, and in which the film is formed with a thickness T₂ less than the thickness T₁ and is formed when the first substance and the third substance are alternately supplied the predetermined number of times.

7. The processing method of claim 1, wherein the cycle includes performing (a) and alternately performing (b) and (c) for m times (m is an integer of 1, or greater than or equal to 2).

8. The processing method of claim 1, wherein the first substance contains a partial structure in which an amino group and an alkyl group are bonded to the first element, or a partial structure in which an amino group and hydrogen are bonded to the first element, and the second substance contains a partial structure in which an amino group and an alkoxy group are bonded to the first element.

9. The processing method of claim 1, wherein the first substance contains one or more chemical bonds between the first element and an alkyl group and three or less chemical bonds between the first element and an amino group in one molecule of the first substance, or contains one or more chemical bonds between the first element and hydrogen and three or less chemical bonds between the first element and an amino group in one molecule of the first substance, and wherein the second substance contains one or more chemical bonds between the first element and an alkoxy group and three or less chemical bonds between the first element and an amino group in one molecule of the second substance.

10. The processing method of claim 1, wherein the first substance includes at least one selected from the group of (dialkylamino)trialkylsilane, bis(dialkylamino)dialkylsilane, tris(dialkylamino)alkylsilane, mono(dialkylamino)silane, bis(dialkylamino)silane, and tris(dialkylamino)silane, and
wherein the second substance includes at least one selected from the group of (dialkylamino)trialkoxysilane, bis(dialkylamino)dialkoxysilane, and tris(dialkylamino)alkoxysilane.

11. The processing method of claim 1, wherein the first substance and the second substance include a partial structure in which an amino group and an alkoxy group are bonded to the first element, a partial structure in which an amino group and an alkyl group are bonded to the first element, or a partial structure in which an amino group and hydrogen are bonded to the first element.

12. The processing method of claim 11, wherein a count of chemical bonds between the first element and the amino group contained in one molecule of the first substance is greater than a count of chemical bonds between the first element and the amino group contained in one molecule of the second substance.

13. The processing method of claim 1, wherein the first substance contains, in one molecule:
two or more chemical bonds between the first element and an amino group; and
two or less chemical bonds between the first element and an alkoxy group, two or less chemical bonds between the first element and an alkyl group, or two or less chemical bonds between the first element and hydrogen, and
wherein the second substance contains, in one molecule:
one chemical bond between the first element and an amino group; and
three chemical bonds between the first element and an alkoxy group, three chemical bonds between the first element and an alkyl group, or three chemical bonds between the first element and hydrogen.

14. The processing method of claim 1, wherein the first substance includes at least one selected from the group of bis(dialkylamino)dialkoxysilane, tris(dialkylamino)alkoxysilane, bis(dialkylamino)dialkylsilane, tris(dialkylamino)alkylsilane, bis(dialkylamino)silane, and tris(dialkylamino)silane, and
wherein the second substance includes at least one selected from the group of (dialkylamino)trialkoxysilane, (dialkylamino)trialkylsilane, and mono(dialkylamino)silane.

15. The processing method of claim 10, wherein the third substance includes at least one selected from the group of O₂ and H₂O.

16. The processing method of claim 14, wherein the third substance includes at least one selected from the group of O₃, O₂+H₂, O radicals, and OH radicals.

17. The processing method of claim 1, wherein the first substance includes at least one selected from the group of bis(dialkylamino)dialkoxysilane and tris(dialkylamino)alkoxysilane,
wherein the second substance includes (dialkylamino)trialkylsilane, and
wherein the third substance includes at least one selected from the group of O₂ and H₂O.

18. A method of manufacturing a semiconductor device, comprising: the processing method of claim 1.

19. A processing apparatus comprising:
a first substance supply system configured to supply a first substance that is chlorine-free and contains a first element to a substrate;
a second substance supply system configured to supply a second substance that is chlorine-free and contains the first element to the substrate;
a third substance supply system configured to supply a third substance containing a second element, which is different from the first element, to the substrate;
a heater configured to heat the substrate; and
a controller configured to be capable of controlling the first substance supply system, the second substance supply system, the third substance supply system, and the heater to perform a process including:
forming a film containing the first element and the second element in a recess on a surface of the substrate by performing a cycle n times (n is an integer of 1, or greater than or equal to 2), the cycle including:
(a) supplying the first substance to the substrate, thereby adsorbing X, which is at least a portion of a molecular structure of molecules constituting the first substance, on an upper portion of the recess;
(b) supplying the second substance to the substrate, thereby adsorbing Y, which is at least a portion of the molecular structure of molecules constituting the second substance, on a portion where X is not adsorbed in the recess and forming a first layer; and
(c) supplying the third substance to the substrate, thereby modifying the first layer to a second layer,
wherein (c) is performed under process conditions in which the film is formed at a first film formation rate when the second substance and the third substance are alternately supplied, and in which the film is formed at a second film formation rate lower than the first film formation rate or is substantially not formed when the first substance and the third substance are alternately supplied.

20. A non-transitory computer-readable recording medium storing a program that causes, by a computer, a processing apparatus to perform a process comprising:
forming a film containing a first element and a second element, which is different from the first element, in a recess on a surface of a substrate by performing a cycle n times (n is an integer of 1, or greater than or equal to 2), the cycle including:
(a) supplying a first substance that is chlorine-free and contains the first element to the substrate, thereby adsorbing X, which is at least a portion of a molecular structure of molecules constituting the first substance to un upper portion of the recess;
(b) supplying a second substance that is chlorine-free and contains the first element to the substrate, thereby adsorbing Y, which is at least a portion of a molecular structure of molecules constituting the second substance on a portion where X is not adsorbed in the recess and forming a first layer; and
(c) supplying a third substance containing the second element to the substrate, thereby modifying the first layer to a second layer,
wherein (c) is performed under process conditions in which the film is formed at a first film formation rate when the second substance and the third substance are alternately supplied, and in which the film is formed at a second film formation rate lower than the first film formation rate or is not substantially formed when the first substance and the third substance are alternately supplied.
